(19) United States
(12) Patent Application Publication
(10) Pub. No.: US 2003/0174551 A1
(43) Pub. Date: Sep. 18, 2003

(54) Method for producing organic light-emitting diodes

(76) Inventors: Georg Wittmann, Herzogenaurach (DE); Matthias Stoessel, Mannheim (DE); Joerg Blaessing, Oberkochen (DE)

Correspondence Address: FISH & RICHARDSON P.C., 500 ARGUELLO STREET, SUITE 500, REDWOOD CITY, CA, 94063, US

(21) Appl. No.: 10/257,079

(22) PCT Filed: Apr. 12, 2001
(86) PCT No.: PCT/DE01/01444

(30) Foreign Application Priority Data
Apr. 12, 2000 (DE) 10018168.6

(51) Int. Cl. G11C 7/00

(52) U.S. Cl. 365/200

(57) ABSTRACT

A method is proposed for manufacturing organic light emitting diodes (OLEDs). While in conventional manufacturing methods, the color conversion layers are applied to a substrate without contact using ink-jet printing methods, printing methods that directly contact the substrate, specifically methods using a printing form, are now used. Flexographic printing and offset printing, for example, operate according to this technology.

The invention relates to a method for manufacturing organic light emitting diodes (OLEDs), which may be used, for example, in the production of flat-panel displays.

The luminance of diodes of the aforementioned type is based on the characteristic of certain organic materials to emit light when connected to a voltage. Depending on the materials used, different color effects may be obtained in this manner. Frequently, the emitter layers made up of the materials named are combined with a color conversion layer. These layers are made of a material that absorbs light waves transmitted by the emitter material and releases them again with a longer wavelength. The color conversion layers may be applied either to an extensive area or in the form of pixels.

A method is known from International Patent WO 98/28946 in which the color conversion layers are applied with a method known from ink-jet printers. The printing methods, also known as ink-jet methods, function without contact in that the color conversion material is applied to the surface to be coated from fine nozzles. Color conversion layers are generally very sensitive to interference factors such as changing layer thicknesses or uneven layer surfaces. However, it is very difficult to achieve a smooth surface using the ink-jet printing method. Moreover, it is difficult to bring about a precise delimitation of the individual pixels.

The object of the present invention is to propose a manufacturing method to make it possible to apply color conversion layers in a technically simple, gentle and reliable manner so that they have a uniform layer thickness and a smooth surface.

According to claim 1, this objective is attained by applying the color conversion layer to a substrate using a printing form.

Printing methods that use a printing form are flatbed printing (e.g., offset printing), letterpress printing (e.g., book printing and flexographic printing), rotogravure and screen printing. In flatbed printing, the printing and nonprinting areas lie in a plane, while in letterpress printing, the printing parts project above the printing form level. In rotogravure, the printing parts are recessed. In screen printing, the most well known representative of which is silk-screen printing, the printing form is a very fine mesh. It is possible to produce both extensive conversion layers as well as those with a pixel array using the printing methods named. Preferably, a glass substrate or a transparent flexible film is used as a substrate.

The invention will now be explained in greater detail with reference to the production of two diodes shown in the appended drawings in which:

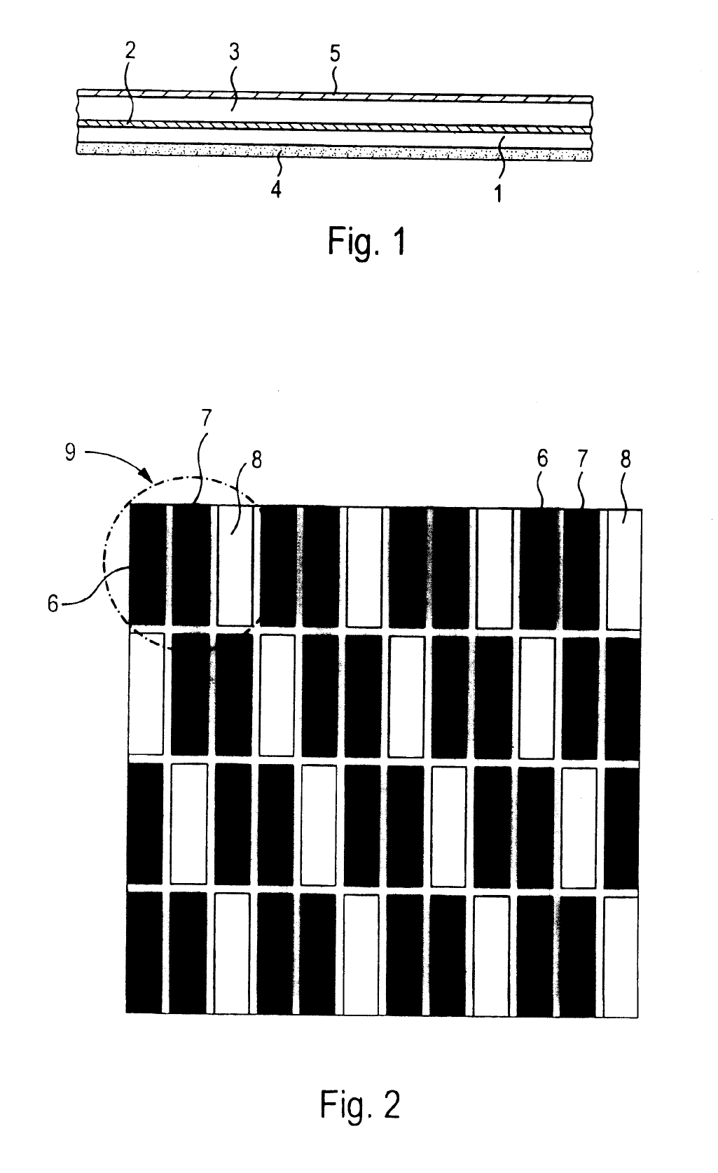

FIG. 1 shows a schematic cross-section through a large-surface monochrome diode and

FIGS. 2-4 shows schematic top views of a diode showing the successive application of the various layers.

A monochrome diode having functional layers applied over large surfaces is shown in FIG. 1. A layer 2 of ITO, which functions as an anode, has been applied to one side of a glass substrate 1. A transparent, flexible film may also be used as a substrate. One or more functional organic layers 3 have been applied to ITO layer 2 by thermal vapor deposition, for example. The functional organic layers 3 have been selected to emit blue light. Calcium has been deposited to the organic layers 3 as a cathode 5. An offset printing method has been used to apply a color conversion layer 4 onto a large surface on the other side of the glass substrate 1.

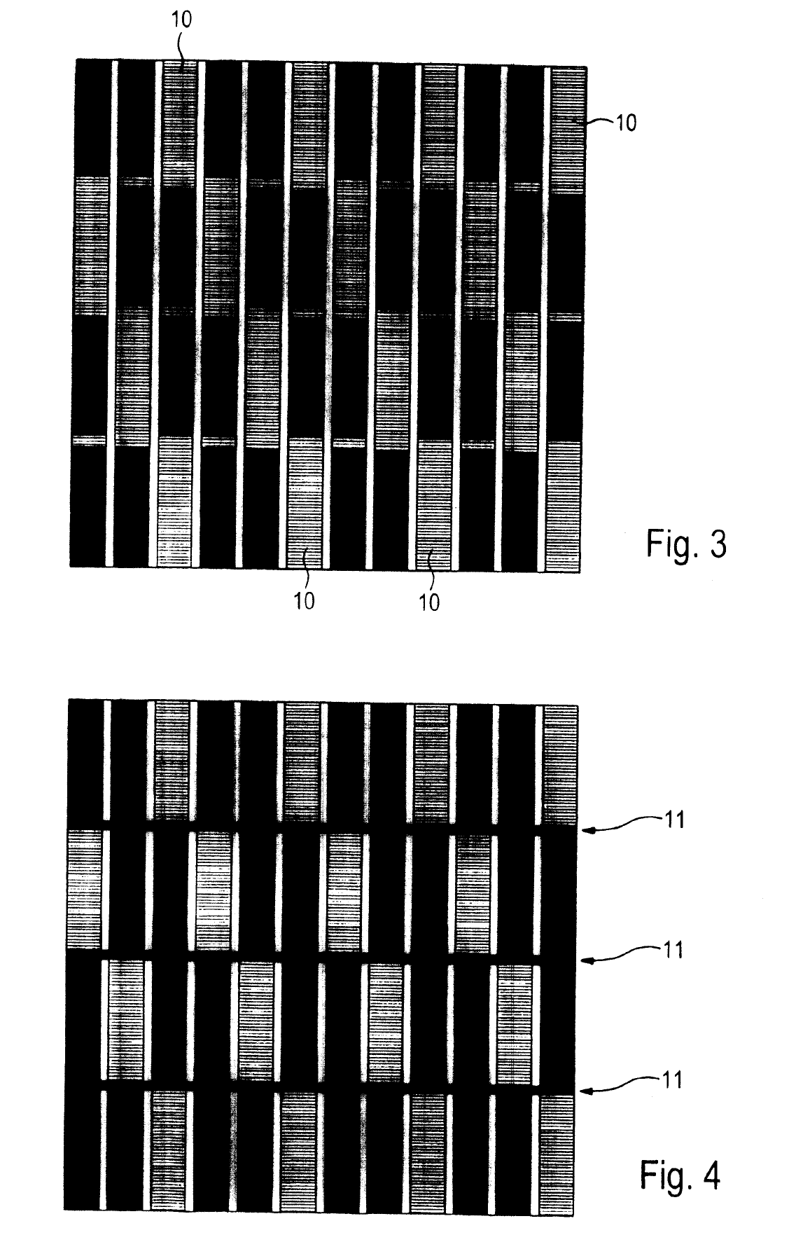

The diode shown in FIGS. 2-4 is an enlarged section of a fully chromatic diode. A color conversion layer is first applied to a glass substrate in the form of a pixel matrix using one of the aforementioned printing methods. In doing so, pixels 6, 7 exchange red and green converting materials with an open space 8. Pixels 6, 7 and open space 8 together form a higher-level pixel 9. Pixels 6, 7 and open pixel 8 have dimensions of approximately 80 μm×280 μm. The distance between the pixels is approximately 20 μm. ITO is now sputtered over the entire surface of this pixel matrix (horizontal hatched line 10 in FIG. 3). This layer is structured by photolithography into parallel strips having a width of 80 μm as well and a spacing of 20 μm. As the next step, photoresist layers 11 having a width of approximately 30 μm are applied at right angles to the ITO strips (FIG. 4). The functional organic layers are now deposited by thermal vapor deposition or by application from solution. Finally, a cathode is deposited by evaporation over the entire surface.

1. A method for manufacturing organic light emitting diodes in which at least one color conversion layer is printed onto a substrate using a printing form.

2. The method according to claim 1, wherein the color conversion layer is printed onto a glass substrate.

3. The method according to claim 1, wherein the color conversion layer is printed onto a transparent, flexible film.
